(19) United States
(12) Patent Application Publication
(10) Pub. No.: US 2025/0122320 A1
(43) Pub. Date: Apr. 17, 2025

(54) CURABLE RESIN, CURABLE RESIN COMPOSITION, AND CURED ARTICLE

(71) Applicant: DIC Corporation, Tokyo (JP)

(72) Inventors: Ryuichi Matsuoka, Sakura-shi (JP); Lichen Yang, Sakura-shi (JP); Hiroyoshi Kannari, Sakura-shi (JP)

(73) Assignee: DIC Corporation, Tokyo (JP)

(21) Appl. No.: 18/725,335

(22) PCT Filed: Jul. 28, 2022
(86) PCT No.: PCT/JP2022/029053

§ 371 Date: Jun. 28, 2024

(30) Foreign Application Priority Data
Jan. 25, 2022 (JP) 2022-009297

(51) Int. Cl. C08F 290/06; C08G 63/21; C08J 5/24; C09D 151/08

(52) U.S. Cl. CPC C08F 290/061; C08F 290/062; C08G 63/21; C08J 5/24; C09D 151/08; C08F 2810/40; C08J 2351/08

(57) ABSTRACT

An object of the present invention is to provide a curable resin composition having excellent solvent solubility, heat resistance (high glass transition temperature), and dielectric properties (low dielectric properties), and a cured article thereof. Specifically, the curable resin composition includes a curable resin (A) that has a repeating unit represented by General Formula (1) and contains one or more reactive groups selected from the group consisting of a (meth)acryloyloxy group, a vinylbenzyl ether group, and an allyl ether group as a terminal structure, and a curable compound (B) represented by General Formula (2).

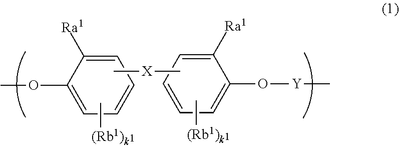

The details of the substituent represented by General Formula (1) and the number of substituents are as described in the specification.

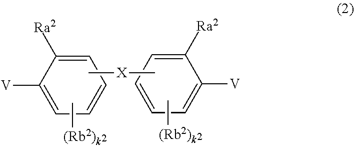

The details of the substituent represented by General Formula (2) and the number of substituents are as described in the specification.

### TECHNICAL FIELD

The present invention relates to a curable resin composition that contains a curable resin having a specific structure and a curable compound, and a cured article obtained from the curable resin composition.

### BACKGROUND ART

With an increase in the amount of information communication in recent years, information communication in a high frequency band has been actively performed, and accordingly, there has been a demand for electrical insulating materials with more excellent electrical properties, particularly a low dielectric constant and a low dielectric loss tangent in order to reduce transmission loss in the high frequency band.

Further, since printed circuit boards or electronic components for which such electronic insulating materials are used are exposed to high-temperature solder low flow during implementation, materials having excellent heat resistance and a high glass transition temperature are required. Particularly, in recent years, lead-free solder having a high melting point is used from the viewpoint of environmental issues, and thus there has been an increasing demand for electrical insulating materials with higher heat resistance.

In response to these demands, vinyl group-containing curable resins having various chemical structures in the related art have been suggested. For example, curable resins such as divinylbenzyl ether of bisphenol and polyvinylbenzyl ether of novolak have been suggested as such curable resins (for example, see PTLs 1 and 2). However, these vinylbenzyl ethers are not capable of providing a cured article with sufficiently low dielectric properties, and a cured article to be obtained has problems in terms of stable use in a high frequency band. In addition, the divinylbenzyl ether of bisphenol does not have sufficiently high heat resistance.

Several polyvinylbenzyl ethers having a specific structure have been suggested in order to improve the dielectric properties and the like of the vinylbenzyl ether with the improved properties described above (for example, see PTLs 3 to 5). However, although attempts have been made to reduce the dielectric loss tangent and to improve the heat resistance, the improvement of these properties is still not sufficient, and accordingly, further improvement of the properties is desired.

As described above, the vinyl group-containing curable resins containing polyvinylbenzyl ether in the related art do not provide a cured article having both a low dielectric loss tangent required for applications in electrical insulating materials and particularly applications in electrical insulating materials dealing with high frequencies and the heat resistance that enables lead-free solder processing. Further, such curable resins have poor solvent solubility that contributes to moldability of a cured article.

### CITATION LIST

### Patent Literature

PTL 1: Japanese Unexamined Patent Application Publication No. S63-68537
PTL 2: Japanese Unexamined Patent Application Publication No. S64-65110
PTL 3: Japanese Unexamined Patent Application Publication No. H1-503238
PTL 4: Japanese Unexamined Patent Application Publication No. H9-31006
PTL 5: Japanese Unexamined Patent Application Publication No. 2005-314556

### SUMMARY OF INVENTION

### Technical Problem

Therefore, an object to be achieved by the present invention is to improve, by using a curable resin composition containing a curable resin having a specific structure and a curable compound, the solvent solubility of the curable resin composition and to provide a cured article with more excellent heat resistance (high glass transition temperature) and more excellent dielectric properties (low dielectric properties).

### Solution to Problem

For this reason, as a result of intensive examination conducted by the present inventors in order to achieve the above-described object, it has been found that a curable resin composition containing a curable resin having a specific structure and a curable compound has excellent solvent solubility and a cured article formed of the curable resin composition has excellent heat resistance and excellent dielectric properties, thereby completing the present invention.

That is, according to the present invention, there is provided a curable resin composition including: a curable resin (A) that has a repeating unit represented by General Formula (1) and contains one or more reactive groups selected from the group consisting of a (meth)acryloyloxy group, a vinylbenzyl ether group, and an allyl ether group as a terminal structure; and a curable compound (B) represented by General Formula (2).

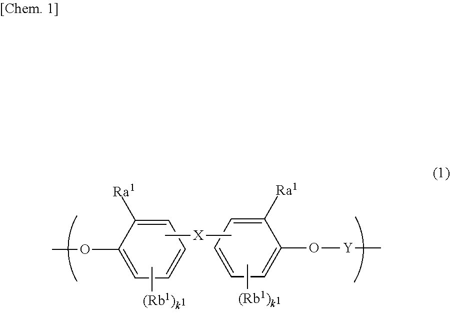

(In the formula, Ra¹ and Rb¹ each independently represent an alkyl group having 1 to 12 carbon atoms, an aryl group, an aralkyl group, or a cycloalkyl group, k¹ represents an integer of 0 to 3, X represents a single bond or a hydrocarbon group, and Y is represented by any of General Formulae (3) to (5).)

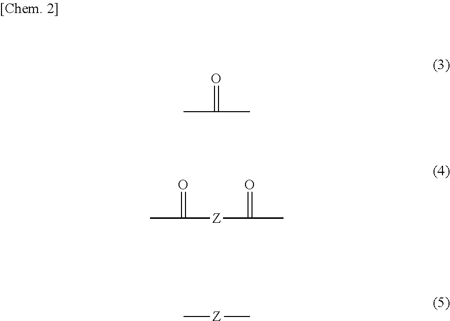

(In the formulae, Z represents a hydrocarbon group.)

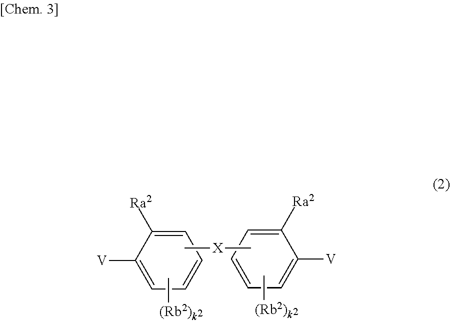

(In the formula, Ra² and Rb² each independently represent an alkyl group having 1 to 12 carbon atoms, an aryl group, an aralkyl group, or a cycloalkyl group, k² represents an integer of 0 to 3, X represents a single bond or a hydrocarbon group, and V represents a (meth)acryloyloxy group, a vinylbenzyl ether group, or an allyl ether group.)

According to the present invention, there is provided a cured article which is obtained by performing a curing reaction on the curable resin composition.

### Advantageous Effects of Invention

The curable resin composition of the present invention can contribute to the solvent solubility, and thus the cured article has excellent moldability. Further, the curable resin composition of the present invention can further contribute to the reactivity, the heat resistance, and the low dielectric properties, and thus the cured article to be obtained has excellent heat resistance and excellent low dielectric properties. Therefore, the curable resin composition is useful.

### BRIEF DESCRIPTION OF DRAWINGS

FIG. 1 is a GPC chart of a curable resin (A1) obtained in Synthesis Example 1.

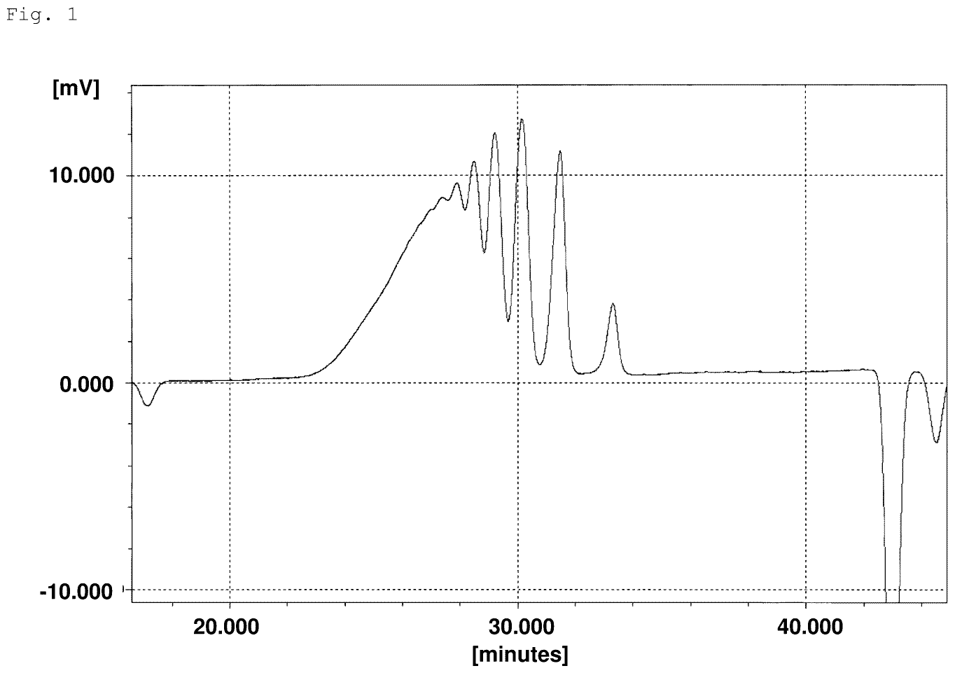

FIG. 2 is a GPC chart of a curable resin (A2) obtained in Synthesis Example 2.

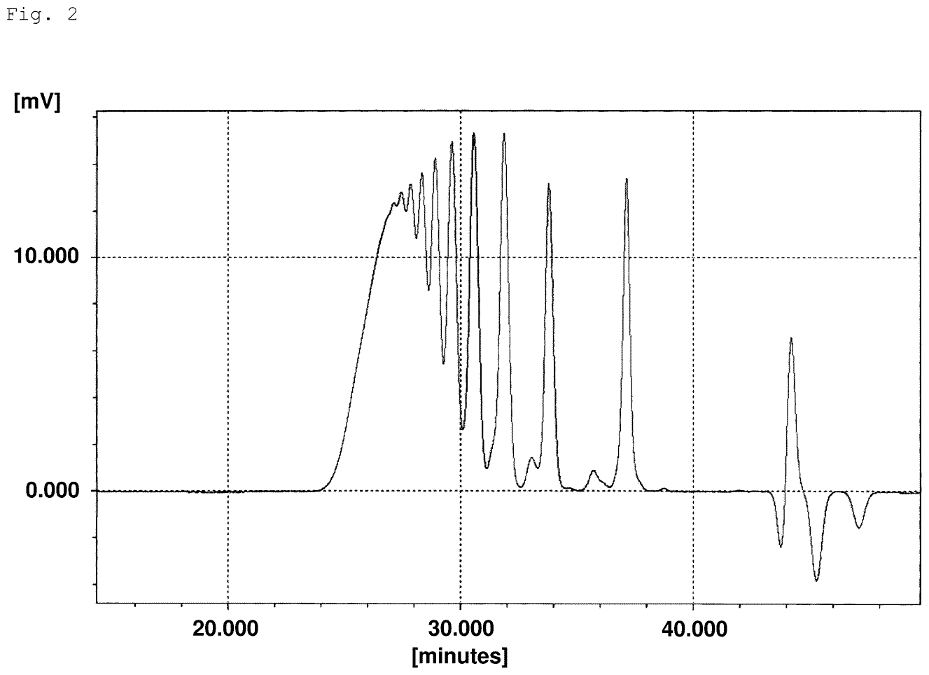

### DESCRIPTION OF EMBODIMENTS

Hereinafter, the present invention will be described in detail.

### <Curable Resin (A)>

A curable resin composition of the present invention contains a curable resin (A) having a repeating unit represented by General Formula (1) and containing one or more reactive groups selected from the group consisting of a (meth)acryloyloxy group, a vinylbenzyl ether group, and an allyl ether group as a terminal structure.

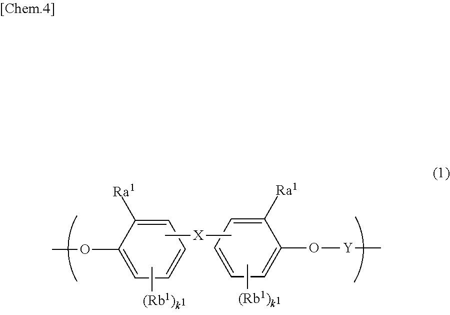

In General Formula (1), Ra¹ and Rb¹ each independently represent an alkyl group having 1 to 12 carbon atoms, an aryl group, an aralkyl group, or a cycloalkyl group, k¹ represents an integer of 0 to 3, X represents a single bond or a hydrocarbon group, and Y is represented by any of General Formulae (3) to (5).

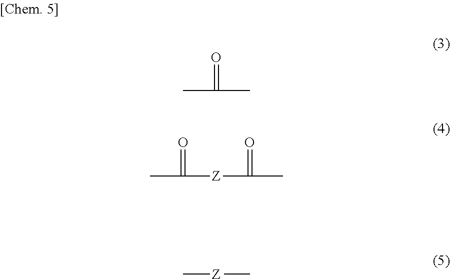

In General Formulae (3) to (5), Z represents a hydrocarbon group.

Since the curable resin (A) has a repeating unit represented by General Formula (1) and one or more reactive groups selected from the group consisting of a (meth)acryloyloxy group, a vinylbenzyl ether group, and an allyl ether group as a terminal structure, an ester bond, a carbonate bond, or an ether bond in the curable resin (A) has low molecular mobility and low dielectric properties (particularly a low dielectric loss tangent), and the polarity derived from the reactive group is restricted by steric hindrance of Ra¹ due to the presence of Ra¹ and Rb¹ (particularly, Ra¹) as a substituent in a site adjacent to the reactive group, and therefore, a cured article with a lower dielectric loss tangent can be obtained, which is preferable. Further, the curable resin contains a reactive group, and thus a cured article to be obtained has excellent heat resistance. In addition, the curable resin has an ester bond, a carbonate bond, or an ether bond with low molecular mobility, a cured article having low dielectric properties and a high glass transition temperature can be obtained.

In General Formula (1), Ra¹ and Rb¹ each independently represent an alkyl group having 1 to 12 carbon atoms, an aryl group, an aralkyl group, or a cycloalkyl group and preferably an alkyl group having 1 to 4 carbon atoms, an aryl group, or a cycloalkyl group. Since Ra¹ and Rb¹ represent an alkyl group having 1 to 12 carbon atoms or the like, the planarity in the vicinity of any of a benzene ring, a naphthalene ring, or an anthracene ring described below is decreased, the crystallinity is decreased, and thus the solvent solubility is improved and the melting point is lowered, which is a preferable aspect.

In General Formula (1), k¹ represents an integer of 0 to 3 and preferably an integer of 0 or 1. When k¹ is in the above-described ranges, the planarity in the vicinity of a benzene ring in General Formula (1) is decreased, the crystallinity is decreased, and thus the solvent solubility is improved and the melting point is lowered, which is a preferable aspect. Further, in a case where k¹ does not represent 0, that is, in a case where Rb¹ as a substituent is present in the vicinity of a reactive group, the polarity derived from the reactive group is restricted by steric hindrance of Rb¹, and a cured article with a low dielectric loss tangent can be obtained, which is preferable.

In General Formula (1), X may represent a single bond or a hydrocarbon group, and from the viewpoint of availability of industrial raw materials, X represents preferably a biphenyl structure or a structure represented by any of General Formulae (4) to (6) and more preferably a structure represented by General Formula (4) particularly from the viewpoint of the balance between the heat resistance and the low dielectric properties.

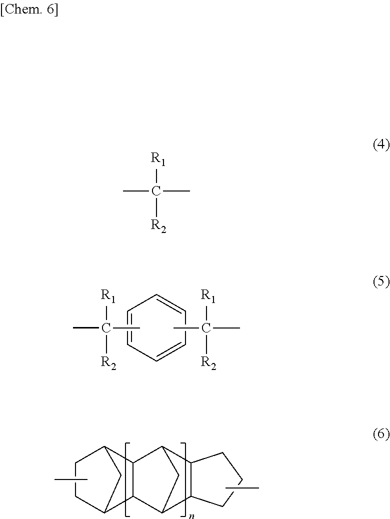

In General Formulae (4) to (7), R₁ and R₂ each independently represent a hydrogen atom, an alkyl group having 1 to 12 carbon atoms, an aryl group, an aralkyl group, or a cycloalkyl group. Alternatively, R₁ and R₂ may be bonded to each other to form a cyclic skeleton. n represents an integer of 0 to 2 and preferably an integer of 0 or 1. When n is in the above-described ranges, the heat resistance is enhanced, which is a preferable aspect.

In General formula (1), Y is represented by any of General Formulae (3) to (5) and preferably by General Formula (3) from the viewpoint of the heat resistance.

In General Formula (4) or (5), Z represents a hydrocarbon group, preferably an alicyclic group, an aromatic group, or a heterocyclic group from the viewpoint of the heat resistance, more preferably a structure represented by any of General Formulae (7) to (11), and still more preferably a structure represented by General Formula (7) particularly from the viewpoints of the cost and the heat resistance.

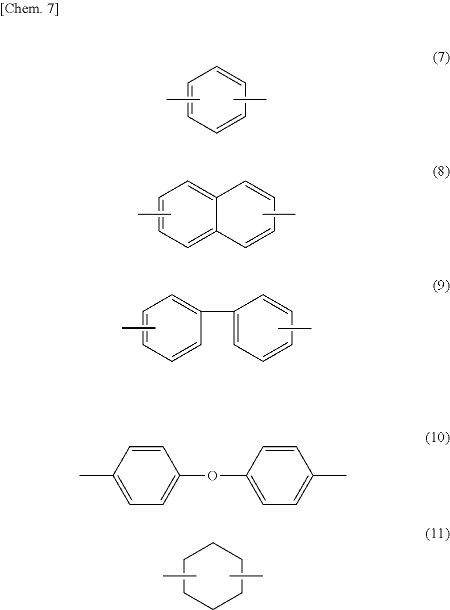

The curable resin (A) of the present invention contains one or more reactive groups selected from the group consisting of a (meth)acryloyloxy group, a vinylbenzyl ether group, and an allyl ether group as a terminal structure and preferably a methacryloyloxy group as the terminal structure from the viewpoint that a cured article to be obtained has a low dielectric loss tangent. The vinylbenzyl ether group and the allyl ether group form an ether bond and tend to have high molecular mobility and a high dielectric loss tangent while the methacryloyloxy group forms an ester bond.

### <Curable Compound (B)>

The curable resin composition of the present invention contains a curable compound (B) represented by General Formula (2).

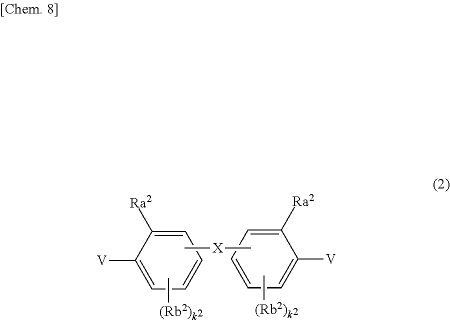

In General Formula (2), Ra² and Rb² each independently represent an alkyl group having 1 to 12 carbon atoms, an aryl group, an aralkyl group, or a cycloalkyl group and preferably an alkyl group having 1 to 4 carbon atoms, an aryl group, or a cycloalkyl group.

In General Formula (2), k² represents an integer of 0 to 3.

In General Formula (2), X represents a single bond or a hydrocarbon group.

In General Formula (2), V represents a (meth)acryloyloxy group, a vinylbenzyl ether group, or an allyl ether group.

Further, Ra², Rb², and k² may be the same as or different from Ra¹, Rb¹, and k¹ in General Formula (1). From the viewpoint of curing properties of a cured article to be obtained, it is preferable that Ra², Rb², and k² be the same as Ra¹, Rb¹, and k¹ in General Formula (1).

When the curable resin composition contains the curable compound (B) represented by General Formula (2), a low-molecular-weight component serves as a starting point for enhancing the solvent solubility, suppressing the deposition rate of the curable resin (A), and enhancing the storage stability of the curable resin composition, which is preferable.

The curable resin composition of the present invention contains the curable compound (B) in a range of 0.5% to 30.0% by area, preferably in a range of 1.0% to 20.0% by area, and more preferably in a range of 1.5% to 15.0% by area when the total amount of the curable resin (A) and the curable compound (B) in units of % by area, which is calculated by measurement of gel permeation chromatography (hereinafter, GPC), is set to 100% by area. In a case where the amount of the curable compound (B) is in the above-described ranges, the solvent solubility of the curable resin composition is excellent, and the heat resistance and the dielectric properties of the cured article to be obtained are excellent, which is preferable.

The curable resin composition is produced by the following method, but it is preferable that the curable compound (B) be separately added from the viewpoint that the content of the curable compound (B) in the resin composition can be easily adjusted. The combination of the curable resin (A) and the curable compound (B) can also be appropriately adjusted depending on the properties required for the cured article.

It is preferable that the curable resin composition of the present invention contain the curable resin (A) in which General Formula (1) has a repeating unit represented by General Formula (1A).

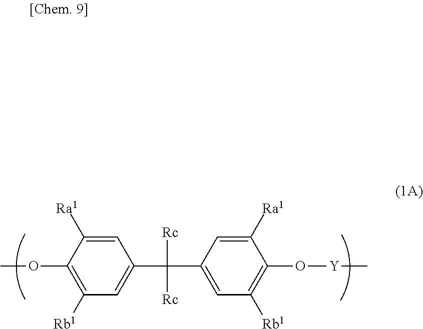

In General Formula (1A), Rc represents an alkyl group, an aryl group, an aralkyl group, or a cycloalkyl group and preferably a methyl group, an ethyl group, an isopropyl group, or a benzyl group. Further, Ra¹, Rb¹, and Y in General Formula (1A) each have the same definition as in the case of General Formula (1).

The curable resin composition of the present invention contains the curable resin (A) having a weight-average molecular weight (Mw) of preferably 500 to 50000, more preferably 1000 to 10000, and still more preferably 1500 to 5000. When the weight-average molecular weight thereof is in the above-described ranges, the solvent solubility is improved, and the processing workability is satisfactory, which is preferable.

### <Method of Producing Curable Resin Composition>

The curable resin composition of the present invention may contain the curable resin (A) and the curable compound (B), and any of a method of separately producing the curable resin (A) and the curable compound (B) and mixing and blending the curable resin (A) and the curable compound (B) or a method of producing the curable resin (A) and the curable compound (B) at the same time in the reaction system may be selected.

### <Method of Producing Curable Resin (A)>

Examples of a method of producing the curable resin (A) according to the present invention include a method of carrying out a reaction in an organic solvent, such as an interfacial polymerization method, and a method of carrying out a reaction in a molten state, such as a solvent polymerization method (reaction step).

### <Interfacial Polymerization Method>

Examples of the interfacial polymerization method include a method of mixing a solution (organic phase) obtained by dissolving a divalent carboxylic acid halide and a reactive group-introducing agent used to introduce a reactive group, which is a terminal structure, in an organic solvent that is incompatible with water with an alkali aqueous solution (aqueous phase) containing dihydric phenol, a polymerization catalyst, and an antioxidant and performing a polymerization reaction while stirring the mixture at a temperature of 50° C. or lower for 1 to 8 hours.

Further, other examples of the interfacial polymerization method include a method of blowing phosgene into a mixture obtained by mixing a solution (organic phase) in which a reactive group-introducing agent used to introduce a reactive group, which is a terminal structure, is dissolved in an organic solvent that is incompatible with water with an alkaline aqueous solution (aqueous phase) containing dihydric phenol, a polymerization catalyst, and an antioxidant and performing a polymerization reaction while stirring the mixture at a temperature of 50° C. or lower for 1 to 8 hours.

A solvent that is incompatible with water and dissolves polyacrylate is preferable as the organic solvent used as an organic phase. Examples of such a solvent include chlorine-based solvents such as methylene chloride, 1,2-dichloroethane, chloroform, carbon tetrachloride, chlorobenzene, 1,1,2,2-tetrachloroethane, 1,1,1-trichloroethane, and o-, m-, or p-dichlorobenzene, aromatic hydrocarbons such as toluene, benzene, and xylene, tetrahydrofuran. Among these, from the viewpoint of ease of use in production, methylene chloride is preferable.

Examples of the alkaline aqueous solution used as an aqueous phase include an aqueous solution of sodium hydroxide and an aqueous solution of potassium hydroxide.

The antioxidant is used to prevent oxidation of a dihydric phenol component. Examples of the antioxidant include sodium hydrosulfite, L-ascorbic acid, erythorbic acid, catechin, tocophenol, and butylated hydroxyanisole. Among these, from the viewpoint of excellent water solubility, sodium hydrosulfite is preferable.

Examples of the polymerization catalyst include quaternary ammonium salts such as tri-n-butylbenzylammonium halide, tetra-n-butylammonium halide, trimethylbenzylammonium halide, and triethylbenzylammonium halide, and quaternary phosphonium salts such as tri-n-butylbenzylphosphonium halide, tetra-n-butylphosphonium halide, trimethylbenzylphosphonium halide, and triethylbenzylphosphonium halide. Among these, from the viewpoint of obtaining a polymer with a high molecular weight and a low acid value, tri-n-butylbenzylammonium halide, trimethylbenzylammonium halide, tetra-n-butylammonium halide, tri-n-butylbenzylphosphonium halide, and tetra-n-butylphosphonium halide are preferable.

The amount of the polymerization catalyst to be added is preferably in a range of 0.01% to 5.0% by mole and more preferably in a range of 0.1% to 1.0% by mole with respect to the number of moles of dihydric phenol used in polymerization. When the amount of the polymerization catalyst to be added is less than 0.01% by mole, the effects of the polymerization catalyst cannot be obtained, and the molecular weight of the polyarylate resin is likely to be decreased, which is not preferable. Meanwhile, when the amount thereof is greater than 5.0% by mole, the hydrolysis reaction of the divalent aromatic carboxylic acid halide is carried out at a higher speed, and thus the molecular weight of the polyarylate resin is likely to be decreased, which is not preferable.

Examples of the dihydric phenol include 2,2-bis(4-hydroxy-3,5-dimethylphenyl)propane, 2,2-bis(4-hydroxy-3,6-dimethylphenyl)propane, 2,2-bis(3-methyl-4-hydroxyphenyl)propane, 2,2-bis(4-hydroxy-3,5,6-trimethylphenyl)propane, 2,2-bis(4-hydroxy-2,3,6-trimethylphenyl)propane, bis(4-hydroxy-3,5-dimethylphenyl)methane, bis(4-hydroxy-3,6-dimethylphenyl)methane, bis(4-hydroxy-3-methylphenyl)methane, bis(4-hydroxy-3,5,6-trimethylphenyl)methane, bis(4-hydroxy-2,3,6-trimethylphenyl)methane, 1,1-bis(4-hydroxy-3,5-dimethylphenyl)-1-phenylethane, 2,2-bis(4-hydroxy-3,5-dimethylphenyl)butane, bis(4-hydroxy-3,5-dimethylphenyl)diphenylmethane, 2,2-bis(4-hydroxy-3-isopropylphenyl)propane, 1,1-bis(4-hydroxy-3,5-dimethylphenyl)ethane, 1,3-bis(2-(4-hydroxy-3,5-dimethylphenyl)-2-propyl)benzene, 1,4-bis(2-(4-hydroxy-3,5-dimethylphenyl)-2-propyl)benzene, 1,1-bis(4-hydroxy-3,5-dimethylphenyl)-3,3,5-trimethylcyclohexane, 1,1-bis(4-hydroxy-3,5-dimethylphenyl)cyclohexane, 2,2-bis(2-hydroxy-5-biphenylyl)propane, and 2,2-bis(4-hydroxy-3-cyclohexyl-6-methylphenyl)propane.

Examples of the divalent carboxylic acid halide include terephthalic acid halide, isophthalic acid halide, orthophthalic acid halide, diphenic acid halide, biphenyl-4,4′-dicarboxylic acid halide, 1,4-naphthalenedicarboxylic acid halide, 2,3-naphthalenedicarboxylic acid halide, 2,6-naphthalenedicarboxylic acid halide, 2,7-naphthalenedicarboxylic acid halide, 1,8-naphthalenedicarboxylic acid halide, 1,5-naphthalenedicarboxylic acid halide, diphenyl ether-2,2′-dicarboxylic acid halide, diphenyl ether-2,3′-dicarboxylic acid halide, diphenyl ether-2,4′-dicarboxylic acid halide, diphenyl ether-3,3′-dicarboxylic acid halide, diphenyl ether-3,4′-dicarboxylic acid halide, diphenyl ether-4,4′-dicarboxylic acid halide, 1,4-cyclohexanedicarboxylic acid halide, and 1,3-cyclohexanedicarboxylic acid halide.

The curable resin has, as a terminal structure, at least one or more reactive groups selected from the group consisting of a (meth)acryloyloxy group, a vinylbenzyl ether group, and an allyl ether group, and a reactive group-introducing agent can be used to introduce these reactive groups. As the reactive group-introducing agent, for example, (meth)acrylic anhydride, (meth)acrylic acid chloride, chloromethylstyrene, chlorostyrene, allyl chloride, and allyl bromide can be used for the reaction. Among these, (meth)acrylic anhydride or (meth)acrylic acid chloride is more preferable particularly from the viewpoint that a cured article formed of a curable resin to which a methacryloyloxy group has been introduced as the terminal structure has a low dielectric loss tangent. The reactive group can be introduced to the curable resin by reacting these compounds, and heat curing properties with a low dielectric constant and a low dielectric loss tangent are obtained, which is a preferable aspect.

Examples of the (meth)acrylic anhydride include acrylic anhydride and methacrylic anhydride. Examples of the (meth)acrylic acid chloride include methacrylic acid chloride and acrylic acid chloride. Further, examples of the chloromethylstyrene include p-chloromethylstyrene and m-chloromethylstyrene, and examples of the chlorostyrene include p-chlorostyrene and m-chlorostyrene. Further, examples of the allyl chloride include 3-chloro-1-propene, and examples of the allyl bromide include 3-bromo-1-propene. These may be used alone or in the form of a mixture. Among these, it is particularly preferable to use methacrylic anhydride or methacrylic acid chloride, in which a cured article with a lower dielectric loss tangent can be obtained.

### <Melt Polymerization Method>

Examples of the melt polymerization method include a method of acetylating dihydric phenol of a raw material and performing deacetylation polymerization on the acetylated dihydric phenol and a divalent carboxylic acid and a method of carrying out a transesterification reaction on dihydric phenol and carbonic acid ester.

In the acetylation reaction, an aromatic dicarboxylic acid component, a dihydric phenol component, and acetic anhydride are put into a reaction container. Thereafter, nitrogen substitution is carried out, and the mixture is stirred at a temperature of 100° C. to 240° C. and preferably 120° C. to 180° C. for 5 minutes to 8 hours and preferably 30 minutes to 5 hours under normal or increased pressure in an inactive atmosphere. The molar ratio of the acetic anhydride to the hydroxyl group of the dihydric phenol component is preferably in a range of 1.00 to 1.20.

The deacetylation polymerization reaction is a reaction in which acetylated dihydric phenol reacts with a divalent carboxylic acid for polycondensation. In the deacetylation polymerization reaction, the mixture is held at a temperature of 240° C. or higher, preferably 260° C. or higher, and more preferably 280° C. or higher at a pressure reduction degree of 500 Pa or less, preferably 260 Pa or less, and more preferably 130 Pa or less for 30 minutes or longer and stirred. In a case of a temperature of lower than 240° C., a pressure reduction degree of greater than 500 Pa, or a holding time of shorter than 30 minutes, the deacetylation polymerization reaction is insufficient, the amount of acetic acid in the polyarylate resin to be obtained is increased, the entire polymerization time is increased, or the polymer color tone is degraded in some cases.

In the acetylation reaction and the deacetylation polymerization reaction, it is preferable to use a catalyst as necessary. Examples of the catalyst include an organic titanic acid compound such as tetrabutyl titanate; zinc acetate; an alkali metal salt such as potassium acetate; an alkaline earth metal salt such as magnesium acetate; antimony trioxide; an organic tin compound such as hydroxybutyl tin oxide or tin octylate; and a heterocyclic compound such as N-methylimidazole. The amount of the catalyst to be added is typically 1.0% by mole or less, more preferably 0.5% by mole or less, and still more preferably 0.2% by mole or less with respect to the total monomer components of the polyarylate resin to be obtained.

The transesterification reaction is carried out in a temperature range of 120° C. to 260° C. and preferably in a range of 160° C. to 200° C. at a pressure of normal pressure to 1 torr for 0.1 to 5 hours and preferably 0.5 to 6 hours.

For example, salts of zinc, tin, zirconium, and lead are preferably used as the catalyst of the transesterification reaction, and these can be used alone or in combination. Specific examples of the transesterification catalyst include zinc acetate, zinc benzoate, zinc 2-ethylhexanoate, tin (II) chloride, tin (IV) chloride, tin (II) acetate, tin (IV) acetate, dibutyl tin dilaurate, dibutyl tin oxide, dibutyl tin dimethoxide, zirconium acetyl acetonate, zirconium oxyacetate, zirconium tetrabutoxide, lead (II) acetate, and lead (IV) acetate. These catalysts are used in a ratio of 0.000001% to 0.1% by mole and preferably in a ratio of 0.00001% to 0.01% by mole with respect to a total of 1 mole of dihydric phenol.

The dihydric phenol in the above-described interfacial polymerization method can be similarly used as the dihydric phenol.

Examples of the divalent carboxylic acid include terephthalic acid, isophthalic acid, orthophthalic acid, diphenic acid, biphenyl-4,4′-dicarboxylic acid, 1,4-naphthalenedicarboxylic acid, 2,3-naphthalenedicarboxylic acid, 2,6-naphthalenedicarboxylic acid, 2,7-naphthalenedicarboxylic acid, 1,8-naphthalenedicarboxylic acid, 1,5-naphthalenedicarboxylic acid, diphenyl ether-2,2′-dicarboxylic acid, diphenyl ether-2,3′-dicarboxylic acid, diphenyl ether-2,4′-dicarboxylic acid, diphenyl ether-3,3′-dicarboxylic acid, diphenyl ether-3,4′-dicarboxylic acid, diphenyl ether-4,4′-dicarboxylic acid, 1,4-cyclohexanedicarboxylic acid, and 1,3-cyclohexanedicarboxylic acid.

Examples of the carbonic acid ester include diphenyl carbonate, ditolyl carbonate, bis(chlorophenyl) carbonate, m-cresyl carbonate, dinaphthyl carbonate, bis(diphenyl) carbonate, diethyl carbonate, dimethyl carbonate, dibutyl carbonate, and dicyclohexyl carbonate.

The curable resin has, as a terminal structure, at least one or more reactive groups selected from the group consisting of a (meth)acryloyloxy group, a vinylbenzyl ether group, and an allyl ether group, and a reactive group-introducing agent can be used to introduce these reactive groups. The reactive group-introducing agent in the interfacial polymerization method described above can be similarly used as the reactive group-introducing agent.

After the reaction step described above, the obtained polymer is washed (washing step). The washing step is classified into solvent washing and water washing. In the solvent washing, a ketone-based solvent, an ester-based solvent, an ether-based solvent, an amide-based solvent, alcohol, and a mixture thereof can be used. The washing step may be performed a plurality of times, and may be performed a plurality of times with different kinds of washing liquids. After the washing, the polymer is dried (drying step).

Examples of a method of simultaneously producing the curable resin (A) and the curable compound (B) include adjustment of the reaction step and adjustment of the purification step. Examples of the method of adjustment by the reaction step include adjustment of the reaction temperature, the reaction time, the amount of the polymerization catalyst to be added, and the like and suppression of an increase in molecular weight of the entire resin. In this manner, the unreacted monomer (curable compound (B)) can remain in the curable resin (A). Further, examples of the method of adjustment by the purification step include washing the polymer with pure water and distillation under reduced pressure.

### <Curable Compound (B)>

A method of producing the curable compound (B) according to the present invention is not particularly limited, and the curable compound (B) can be produced by using a known method of the related art as appropriate. According to an embodiment, for example, a method of mixing a solution (organic phase), obtained by dissolving a reactive group-introducing agent in an organic solvent that is incompatible with water, with an alkaline aqueous solution (aqueous phase) containing dihydric phenol and an antioxidant and carrying out a reaction while stirring the mixture at a temperature of 50° C. or lower for 1 to 8 hours may be employed.

The dihydric phenol in the method of producing the curable resin (A) described above can be similarly used as the dihydric phenol.

Any of a (meth)acryloyloxy group, a vinylbenzyl ether group, or allyl ether group is used as the reactive group of the curable compound (B), and a reactive group-introducing agent can be used to introduce these reactive groups. Further, the reactive group-introducing agent in the method of producing the curable resin (A) described above can be similarly used as the reactive group-introducing agent. In addition, from the viewpoint of the curing properties of the cured article, it is preferable that the reactive group to be introduced to the curable compound (B) be the same as the reactive group of the curable resin (A).

The antioxidant in the interfacial polymerization method described above can be similarly used as the antioxidant.

### <Other Resins and the Like>

In addition to the curable resin (A) and the curable compound (B), other resins, curing agents, curing accelerators, and the like can be used for the curable resin composition of the present invention without particular limitation within a range where the purpose of the present invention is not impaired. As described below, a cured article can be obtained, for example, by heating the curable resin composition without blending a curing agent into the curable resin composition, but the curable resin composition can be used by being blended with a curing agent or a curable accelerator in a case where other resins and the like are blended in combination.

Further, the curable resin composition of the present invention contains the curable resin (A), and in a case where an allyl ether group is introduced to the curable resin (A) as the reactive group of the terminal structure, the reactive group is different from the (meth)acryloyloxy group and the vinylbenzyl ether group and cannot perform homopolymerization (crosslinking or self-curing) (a cured article cannot be obtained by the allyl ether group alone). Therefore, a curing agent, a curing accelerator, or the like is required to be used in a case where the allyl ether group serves as the reactive group.

### <Other Resins>

As the other resins, for example, a styrene butadiene resin, a styrene-butadiene-styrene block resin, a styrene-isoprene-styrene resin, a styrene-maleic anhydride resin, an acrylonitrile butadiene resin, a polybutadiene resin, or a hydrogenated resin thereof, an acrylic resin, and a silicone resin can be used. When the thermoplastic resin is used, the properties attributed to the resin can be imparted to the cured article, which is a preferable aspect. For example, the use of the thermoplastic resin can contribute to imparting, as the performance that can be imparted, moldability, high-frequency properties, conductor adhesiveness, solder heat resistance, adjustment of the glass transition temperature, the thermal expansion coefficient, and smear removal properties.

### <Curing Agent>

Examples of the curing agent include an amine-based compound, an amide-based compound, an acid anhydride-based compound, a phenolic compound, and a cyanate ester compound. These curing agents may be used alone or in combination of two or more kinds thereof.

### <Curing Accelerator>

Various kinds of curing accelerators can be used as the curing accelerator, and examples thereof include a phosphorus-based compound, a tertiary amine, imidazoles, an organic acid metal salt, a Lewis acid, and an amine complex salt. Particularly in a case where the curing accelerator is used as a semiconductor sealing material, a phosphorus-based compound such as triphenyl phosphine or imidazoles are preferable from the viewpoint that the curing properties, the heat resistance, the electrical properties, the moisture resistance reliability, and the like are excellent. These curing accelerators may be used alone or in combination of two or more kinds thereof.

### <Flame Retardant>

A flame retardant can be blended into the curable resin composition of the present invention in order to exhibit flame retardancy as necessary. Among flame retardants, it is preferable that a non-halogen-based flame retardant containing substantially no halogen atoms be blended into the curable resin composition. Examples of the non-halogen-based flame retardant include a phosphorus-based flame retardant, a nitrogen-based flame retardant, a silicone-based flame retardant, an inorganic flame retardant, and an organic metal salt-based flame retardant, and these flame retardants may be used alone or in combination of two or more kinds thereof.

### <Filler>

An inorganic filler can be blended into the curable resin composition of the present invention as necessary. Examples of the inorganic filler include fused silica, crystalline silica, alumina, silicon nitride, and aluminum hydroxide. In a case where the amount of the inorganic filler to be blended is particularly increased, it is preferable to use fused silica. Any of crushed fused silica or spherical fused silica can be used as the fused silica, but it is preferable to mainly use the spherical fused silica in order to increase the amount of fused silica to be blended and to suppress an increase in the melt viscosity of the molded material. In order to further increase the amount of spherical silica to be blended, it is preferable to appropriately adjust the particle size distribution of the spherical silica. Further, a conductive filler such as silver powder or copper powder can be used in a case where the curable resin composition is used for applications such as a conductive paste described below.

### <Other Blending Agents>

Various blending agents such as a silane coupling agent, a release agent, a pigment, and an emulsifier can be added to the curable resin composition of the present invention as necessary.

### <Cured Article>

The present invention relates to a cured article obtained by performing a curing reaction on the curable resin composition. The curable resin composition of the present invention can be obtained by uniformly mixing each component such as the above-described flame retardant depending on the purpose thereof, and can be easily formed into a cured article by the same method as a method known in the related art. Examples of the cured article include a molded and cured article such as a laminate, a cast substance, an adhesive layer, a coating film, or a film.

Examples of the curing reaction include a heat curing reaction and an ultraviolet curing reaction. Among these, the heat curing reaction is easily carried out without a catalyst, but in a case where the reaction is intended to be carried out at a higher speed, it is effective to add a polymerization initiator such as an organic peroxide or an azo compound, and a basic catalyst such as a phosphine-based compound or a tertiary amine to the curable resin composition. Examples thereof include benzoyl peroxide, dicumyl peroxide, azobisisobutyronitrile, triphenyl phosphine, triethylamine, and imidazoles.

### <Applications>

The cured article formed of the curable resin composition of the present invention has excellent heat resistance and excellent low dielectric properties and thus can be suitably used as a heat-resistant member or an electronic member. Particularly, the cured article can be suitably used as a prepreg, a circuit board, a semiconductor sealing material, a semiconductor device, a build-up film, a build-up board, an adhesive, a resist material, or the like. Further, the cured article can also be suitably used as a matrix resin of a fiber-reinforcing resin and thus is particularly suitable as a prepreg with high heat resistance. The curable resin composition of the present invention exhibits excellent solubility in various solvents, and thus can be formed into a coating material. The heat-resistant member or the electronic member obtained as described above can be suitably used for various applications, and examples thereof include industrial machine components, general machine components, components of automobiles, railways, and vehicles, aerospace components, electronic and electrical components, building materials, containers, packaging members, daily necessities, sports and leisure goods, and housing members for wind power generation, but the present invention is not limited thereto.

Hereinafter, representative products to be produced by using the curable resin composition of the present invention will be described with reference to examples.

### <Varnish>

The present invention relates to a varnish obtained by diluting the curable resin composition with an organic solvent. A known method can be used as a method of preparing the varnish, and the curable resin composition can be formed into a resin varnish dissolved in (diluted with) an organic solvent. The curable resin composition of the present invention has high solvent solubility and can be suitably used.

As the solvent, at least one solvent selected from a ketone-based solvent, an ester-based solvent, an ether-based solvent, an amide-based solvent, or alcohol is preferable, and a solvent selected from toluene, methyl ethyl ketone, or cyclohexanone is more preferable.

### <Prepreg>

The present invention relates to a prepreg containing a reinforcing base material and a semi-cured article of the varnish impregnated into the reinforcing base material. A prepreg can be formed by impregnating the reinforcing base material with the varnish (resin varnish), performing a heat treatment on the reinforcing base material, and semi-curing (or uncuring) the curable resin composition. The conditions for the heat treatment are appropriately selected according to the kinds of the organic solvent, the catalyst, and various additives to be used and the amounts thereof to be used, and the heat treatment is typically performed under conditions of a temperature of 80° C. to 220° C. for 3 minutes to 30 minutes.

The organic solvent can be used alone or in the form of a mixed solvent of two or more kinds selected from, for example, toluene, xylene, N,N-dimethylformamide, N,N-dimethylacetamide, N-methyl-2-pyrrolidone, methyl ethyl ketone (MEK), methyl isobutyl ketone, dioxane, and tetrahydrofuran.

Examples of the reinforcing base material impregnated with the varnish (resin varnish) include woven or nonwoven fabrics, mats, or paper, formed of inorganic fibers such as glass fibers, polyester fibers, and polyamide fibers and organic fibers, and these may be used alone or in combination. The mass proportion of the curable resin composition and the reinforcing base material is not particularly limited, but it is preferable that the mass proportion thereof be adjusted such that the proportion of the curable resin composition (the content of the resin therein) in the prepreg is in a range of 20% to 60% by mass.

### <Laminate>

It is preferable that the laminate contain a cured article obtained by curing the curable resin composition. As the laminate, a laminate formed of a base material and a layer containing the cured article (cured article layer) has a low dielectric constant, a low dielectric loss tangent, and high heat resistance, and thus can be used as a printed circuit board compatible with a high frequency, which is preferable.

As the base material used for the laminate, for example, an inorganic material such as a metal or glass and an organic material such as plastics or wood may be appropriately used depending on the applications thereof, and examples thereof include glass fibers such as E glass, D glass, S glass, Q glass, spherical glass, NE glass, L glass, T glass, and inorganic fibers; quartz and wholly aromatic polyamide; poly-paraphenylene terephthalamide (Kevlar (registered trademark), manufactured by Du Pont), copolyparaphenylene-3,4′-oxydiphenylene-terephthalamide (Technora (registered trademark), manufactured by Teijin Techno Products Limited); polyester such as 2,6-hydroxynaphthoic acid-parahydroxybenzoic acid (Vectran (registered trademark), manufactured by KURARAY CO., LTD.), Zexion (registered trademark, manufactured by KB SEIREN LTD.); and organic fibers such as poly p-phenylenebenzobisoxazole (Zylon (registered trademark), manufactured by TOYOBO XO., LTD.) and polyimide.

The laminate may have a shape such as a flat plate shape, a sheet shape, or a three-dimensional structure or a three-dimensional shape. The laminate may have an optional shape, for example, a curvature over the entire surface or a part thereof, depending on the purpose thereof. Further, the hardness, the thickness, or the like of the base material is not limited. Further, the cured article may be used as the base material, and a cured article may be further laminated thereon.

In a case where the laminate is used as a circuit board or a semiconductor package substrate, metal foil is preferably laminated thereon, and examples of the metal foil include copper foil, aluminum foil, gold foil, and silver foil. Among these, from the viewpoint of satisfactory processability, it is preferable to use copper foil.

A layer containing the cured article (cured article layer) in the laminate may be formed by direct coating or direct molding with respect to the base material, and a substance that has been molded in advance may be laminated thereon. In a case of direct coating, a coating method is not particularly limited, and examples thereof include a spray method, a spin coating method, a dip method, a roll coating method, a blade coating method, a doctor roll method, a doctor blade method, a curtain coating method, a slit coating method, a screen printing method, and an ink jet method. In a case of direct molding, examples thereof include in-mold molding, insert molding, vacuum molding, extrusion lamination molding, and press molding.

Further, a precursor that can be used as the base material may be laminated on the cured article by coating the cured article with the precursor and curing the precursor, or a precursor that can be used as the base material or the curable resin composition of the present invention may be cured after adhesion to the cured article in an uncured or semi-cured state. The precursor that can be used as the base material is not particularly limited, and various curable resin compositions and the like can also be used.

### <Circuit Board>

The present invention relates to a circuit board containing the prepreg. Specific examples of a method of obtaining the circuit board from the curable resin composition of the present invention include a method of laminating the prepreg using a known method, overlapping copper foil as appropriate, performing thermocompression bonding and molding at 170° C. to 300° C. under a pressure of 1 to 10 MPa for 10 minutes to 3 hours.

### <Semiconductor Sealing Material>

It is preferable that the semiconductor sealing material contain the curable resin composition. Specific examples of a method of obtaining the semiconductor sealing material from the curable resin composition of the present invention include a method of sufficiently melting and mixing, as necessary, a blending agent such as a curing accelerator or an inorganic filler, which is a further optional component, into the curable resin composition using an extruder, a kneader, a roll, or the like until a uniform mixture is obtained. Here, fused silica is typically used as the inorganic filler, but in a case where an inorganic filler is used as a power transistor, a highly thermally conductive semiconductor sealing material for a power IC, highly filled crystallin silica, alumina, silicon nitride, or the like with a thermal conductivity higher than that of fused silica, or fused silica, crystalline silica, alumina, silicon nitride, or the like may be used. The filling rate is set such that the content of the inorganic filler is preferably in a range of 30 to 95 parts by mass, and from the viewpoint of improving the flame retardancy, the moisture resistance, and the solder crack resistance and reducing the linear expansion coefficient, the content thereof is more preferably 70 parts by mass or greater and still more preferably 80 parts by mass or greater with respect to 100 parts by mass of the curable resin composition.

### <Semiconductor Device>

It is preferable that a semiconductor device contain a cured article obtained by heating and curing the semiconductor sealing material. Specific examples of a semiconductor package molding method of obtaining a semiconductor device from the curable resin composition according to the present invention include a method of casting the semiconductor sealing material or molding the semiconductor sealing material using a transfer molding machine, an injection molding machine, or the like, and heating and curing the semiconductor sealing material at 50° C. to 250° C. for 2 to 10 hours.

### <Build-Up Board>

Examples of a method of obtaining a build-up board from the curable resin composition according to the present invention include a method of performing steps 1 to 3. In the step 1, first, a circuit board on which a circuit is formed is coated with the curable resin composition blended with rubber, a filler, or the like as appropriate using a spray coating method, a curtain coating method, or the like, and the curable resin composition is cured. In the step 2, the circuit board coated with the curable resin composition is punched to form a predetermined through-hole portion as necessary and treated with a roughening agent, the surface of the circuit board is washed with hot water to form unevenness on the board, and subjected to a plating treatment with a metal such as copper. In the step 3, the operations in the steps 1 and 2 are sequentially repeated as desired, and resin insulating layers and conductor layers having a predetermined circuit pattern are alternately built up to mold a build-up board. Further, in the step, the punching for the through-hole portion may be performed after formation of the resin insulating layer which is an outermost layer. Further, the build-up board in the present invention can also be prepared by, on the circuit board on which a circuit is formed, thermocompression-bonding copper foil provided with a resin obtained by semi-curing the resin composition on copper foil, at 170° C. to 300° C. to form a roughened surface without performing the step of the plating treatment.

### <Build-Up Film>

It is preferable that a build-up film contain the curable resin composition. Examples of a method of obtaining the build-up film from the curable resin composition according to the present invention include a method of coating a support film with the curable resin composition, drying the composition, and forming a resin composition layer on the support film. In a case where the curable resin composition of the present invention is used in the build-up film, it is important that the film be softened under a temperature condition (typically in a range of 70° C. to 140° C.) for lamination in a vacuum lamination method and exhibit fluidity (resin flow) that enables a via hole or a through-hole present in the circuit board to be filled with a resin simultaneously with the lamination of the circuit board, and it is preferable that each of the components be blended such that these properties are exhibited.

Here, the diameter of the through-hole of the circuit board is typically in a range of 0.1 to 0.5 mm, and the depth thereof is typically in a range of 0.1 to 1.2 mm, and it is preferable that the through-hole can be filled with the resin typically within the above-described ranges. Further, it is desirable that about ½ of the through-hole is filled with the resin in a case of lamination of both surfaces of the circuit board.

Specific examples of a method of producing the build-up film described above include a method of blending an organic solvent to prepare a resin composition formed into a varnish, coating a surface of a support film (Y) with the resin composition formed into a varnish, and drying the organic solvent by heating or blowing hot air to the organic solvent to form a resin composition layer (X).

Preferred examples of the organic solvent used here include ketones such as acetone, methyl ethyl ketone, and cyclohexanone, acetic acid esters such as ethyl acetate, butyl acetate, cellosolve acetate, propylene glycol monomethyl ether acetate, and carbitol acetate, carbitols such as cellosolve and butyl carbitol, aromatic hydrocarbons such as toluene and xylene, dimethylformamide, dimethylacetamide, and N-methylpyrrolidone. Further, it is preferable that the proportion of the organic solvent be set such that the non-volatile content is in a range of 30% to 60% by mass.

Further, the thickness of the resin composition layer (X) to be formed is required to be typically greater than or equal to the thickness of the conductor layer. Since the thickness of the conductor layer of the circuit board is typically in a range of 5 to 70 μm, the thickness of the resin composition layer (X) is preferably in a range of 10 to 100 μm. Further, the resin composition layer (X) in the present invention may be protected by a protective film described below. When the resin composition layer (X) is protected by a protective film, adhesion of dirt and the like to the surface of the resin composition layer and occurrence of scratches on the surface thereof can be prevented.

Examples of the support film and the protective film include polyolefin such as polyethylene, polypropylene, or polyvinyl chloride, polyester such as polyethylene terephthalate (PET) or polyethylene naphthalate, polycarbonate, polyimide, release paper, and metal foil such as copper foil or aluminum foil. Further, the support film and the protective film may be subjected to a MAD treatment, a corona treatment, or a release treatment. The thickness of the support film is not particularly limited, but is typically in a range of 10 to 150 μm and preferably in a range of 25 to 50 μm. Further, the thickness of the protective film is preferably in a range of 1 to 40 μm.

The support film (Y) is peeled off after being laminated on the circuit board or performing heating and curing to form an insulating layer. In a case where the support film (Y) is peeled off after the resin composition layer constituting the build-up film is heated and cured, adhesion of dirt and the like in the curing step can be prevented. When the support film (Y) is peeled off after the resin composition layer is cured, the support film is typically subjected to a release treatment.

Further, a multilayer printed circuit board can be produced from the build-up film obtained as described above. For example, in a case where the resin composition layer (X) is protected by the protective film, the resin composition layer and the protective film are peeled off and laminated using, for example, a vacuum lamination method on one surface or both surfaces of the circuit board such that the resin composition layer (X) is in direct contact with the circuit board. The lamination method may be batch type method or a continuous type method using a roll. Further, the build-up film and the circuit board may be heated (preheated) as necessary before the lamination. The lamination is performed preferably under conditions of a pressure-bonding temperature (lamination temperature) of 70° C. to 140° C., a pressure-bonding pressure of 1 to 11 kgf/cm² (9.8×10⁴ to 107.9×10⁴ N/m²), and a reduced air pressure of 20 mmHg (26.7 hPa) or less.

### <Conductive Paste>

Examples of a method of obtaining a conductive paste from the curable resin composition according to the present invention include a method of dispersing conductive particles in the composition. A paste resin composition for circuit connection or an anisotropic conductive adhesive can be used as the conductive paste depending on the kind of the conductive particles to be used.

### EXAMPLES

Hereinafter, the present invention will be described in detail with reference to examples and comparative examples, and “parts” and “%” are on a mass basis unless otherwise specified. Further, curable resins, curable compounds, and cured articles obtained by using the curable resins and the curable compounds were prepared under the conditions described below, and the obtained cured articles were measured and evaluated under the conditions described below.

### <GPC Measurement (Evaluation of Weight-Average Molecular Weight (Mw) of Curable Resin)>

The weight-average molecular weight (Mw) and the area % of the curable resin obtained by the following synthesis method were calculated after measurement carried out using the following measuring device under the following measurement conditions.
Measuring device: “HLC-8320 GPC” (manufactured by Tosoh Corporation)
Columns: Guard Column “HXL-L” (manufactured by Tosoh Corporation)+“TSK-GEL G2000HXL” (manufactured by Tosoh Corporation)+“TSK-GEL G2000HXL” (manufactured by Tosoh Corporation)+“TSK-GEL G3000HXL” (manufactured by Tosoh Corporation)+“TSK-GEL G4000HXL” (manufactured by Tosoh Corporation)
Detector: RI (differential refractometer)
Deta processing: “GPC WorkStation EcoSEC-WorkStation” (manufactured by Tosoh Corporation)
Measurement condition: column temperature of 40° C.
Developing solvent: tetrahydrofuran
Flow rate: 1.0 ml/min
Standard: The following monodisperse polystyrene with a known molecular weight was used in conformity with the measurement manual described in “GPC WorkStation EcoSEC-WorkStation”.

### (Polystyrene Used)

“A-500” (manufactured by Tosoh Corporation)
“A-5000” (manufactured by Tosoh Corporation)
“A-2500” (manufactured by Tosoh Corporation)
“A-5000” (manufactured by Tosoh Corporation)
“F-1” (manufactured by Tosoh Corporation)
“F-2” (manufactured by Tosoh Corporation)
“F-4” (manufactured by Tosoh Corporation)
“F-10” (manufactured by Tosoh Corporation)
“F-20” (manufactured by Tosoh Corporation)
“F-40” (manufactured by Tosoh Corporation)
“F-80” (manufactured by Tosoh Corporation)
“F-128” (manufactured by Tosoh Corporation)

Sample: A 1.0 mass % tetrahydrofuran solution in terms of solid content of the curable resin obtained in each example and each comparative example, which had been filtered through a microfilter (50 μl) was used.

### Synthesis Example 1

A reaction container provided with a stirring device was charged with 113.8 parts by mass of 2,2-bis(4-hydroxy-3,5-dimethylphenyl)propane, 64.0 parts by mass of sodium hydroxide, 0.25 parts by mass of tri-n-butylbenzylammonium chloride, and 2000 parts by mass of pure water, and the mixture was dissolved to prepare an aqueous phase. 30.5 parts by mass of terephthalic acid dichloride, 30.5 parts by mass of isophthalic acid dichloride, and 20.9 parts by mass of methacrylic acid chloride were dissolved in 1500 parts by mass of methylene chloride to prepare an organic phase.

The aqueous phase was stirred in advance, the organic phase was added to the aqueous phase while the mixture was strongly stirred, and the mixture was allowed to react at 20° C. for 5 hours. Thereafter, the stirring was stopped, the aqueous phase and the organic phase were separated from each other, and the organic phase was washed with pure water 10 times. Next, the methylene chloride was distilled from the organic phase using an evaporator under reduced pressure, and a polymer obtained by the reaction was dried and solidified. The solid matter was washed with a mixed solution of 1 L of methanol and 200 ml of tetrahydrofuran twice, washed with 1 L of hot water twice, and dried at 80° C. under reduced pressure, thereby obtaining a curable resin (A1) having the following repeating unit, containing a methacryloyloxy group with a weight-average molecular weight of 3300 at the terminal, and containing 0% by area of 2,2-bis(4-hydroxy-3,5-dimethylphenyl)propane dimethacrylate.

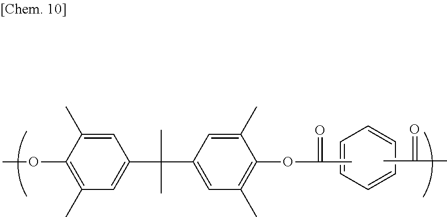

### Synthesis Example 2

A reaction container provided with a stirring device was charged with 113.8 parts by mass of 2,2-bis(4-hydroxy-3,5-dimethylphenyl)propane, 64.0 parts by mass of sodium hydroxide, 0.25 parts by mass of tri-n-butylbenzylammonium chloride, and 2000 parts by mass of pure water, and the mixture was dissolved to prepare an aqueous phase. 30.5 parts by mass of terephthalic acid dichloride, 30.5 parts by mass of isophthalic acid dichloride, and 20.9 parts by mass of methacrylic acid chloride were dissolved in 1500 parts by mass of methylene chloride to prepare an organic phase.

The aqueous phase was stirred in advance, the organic phase was added to the aqueous phase while the mixture was strongly stirred, and the mixture was allowed to react at 20° C. for 5 hours. Thereafter, the stirring was stopped, the aqueous phase and the organic phase were separated from each other, and the organic phase was washed with pure water 10 times. Next, the methylene chloride was distilled from the organic phase using an evaporator under reduced pressure, and a polymer obtained by the reaction was dried and solidified. The obtained polymer was dried under reduced pressure, thereby obtaining a curable resin (A2) having the following repeating unit, containing a methacryloyloxy group with a weight-average molecular weight of 3100 at the terminal, and containing 7% by area of 2,2-bis(4-hydroxy-3,5-dimethylphenyl)propane dimethacrylate.

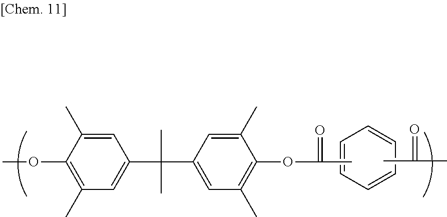

### Synthesis Example 3

The synthesis was performed by the same method as in Synthesis Example 2 except that 2,2-bis(4-hydroxy-3,5-dimethylphenyl)propane in Synthesis Example 2 was changed to 157.0 parts by mass of 2,2-bis(4-hydroxy-3-cyclohexyl-6-methylphenyl)propane, thereby obtaining a curable resin (A3) having the following repeating unit, containing a methacryloyloxy group with a weight-average molecular weight of 3200 at the terminal, and containing 7% by area of 2,2-bis(4-hydroxy-3-cyclohexyl-6-methylphenyl)propane dimethacrylate.

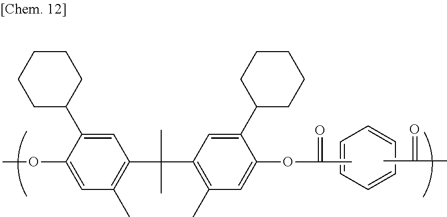

### Synthesis Example 4

The synthesis was performed by the same method as in Synthesis Example 2 except that terephthalic acid dichloride and isophthalic acid dichloride in Synthesis Example 2 were changed to 62.7 parts by mass of 1,4-cyclohexanedicarboxylic acid dichloride, thereby obtaining a curable resin (A4) having the following repeating unit, containing a methacryloyloxy group with a weight-average molecular weight of 3100 at the terminal, and containing 8% by area of 2,2-bis(4-hydroxy-3,5-dimethylphenyl)propane dimethacrylate.

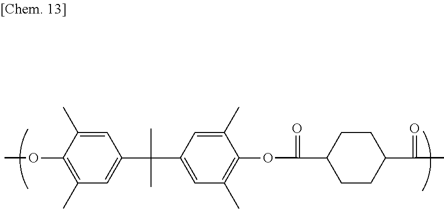

### Synthesis Example 5

The synthesis was performed by the same method as in Synthesis Example 2 except that 2,2-bis(4-hydroxy-3,5-dimethylphenyl)propane in Synthesis Example 2 was changed to 91.3 parts by mass of 2,2-bis(4-hydroxyphenyl)propane, thereby obtaining a curable resin (A5) having the following repeating unit, containing a methacryloyloxy group with a weight-average molecular weight of 3000 at the terminal, and containing 9% by area of 2,2-bis(4-hydroxyphenyl)propane dimethacrylate.

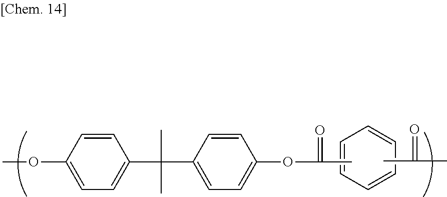

### Synthesis Example 6

The synthesis was performed by the same method as in Synthesis Example 2 except that methacrylic acid chloride in Synthesis Example 2 was changed to 30.5 parts by mass of chloromethylstyrene, thereby obtaining a curable resin (A6) having the following repeating unit, containing a vinylbenzyl ether group with a weight-average molecular weight of 3100 at the terminal, and containing 8% by area of 2,2-bis(4-hydroxy-3,5-dimethylphenyl)propane dimethacrylate.

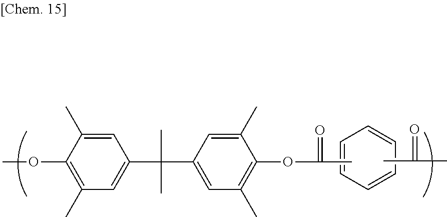

### Synthesis Example 7

The synthesis was performed by the same method as in Synthesis Example 2 except that methacrylic acid chloride in Synthesis Example 2 was changed to 15.3 parts by mass of allyl chloride, thereby obtaining a curable resin (A7) having the following repeating unit, containing an allyl ether group with a weight-average molecular weight of 3100 at the terminal, and containing 8% by area of 2,2-bis(4-hydroxy-3,5-dimethylphenyl)propane dimethacrylate.

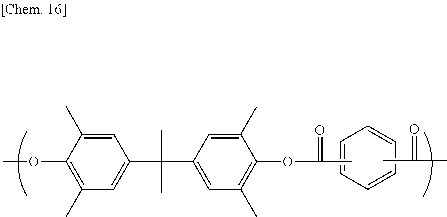

### Synthesis Example 8

A reaction container provided with a stirring device, a distillation column, and a pressure reducing device was charged with 113.8 parts by mass of 2,2-(bis(4-hydroxy-3,5-dimethylphenyl)propane, 64.2 parts by mass of diphenyl carbonate, 0.01 parts by mass of tetramethylammonium hydroxide, and the mixture was dissolved at 140° C. after nitrogen substitution. The mixture was stirred for 30 minutes, the internal temperature was increased to 180° C., the mixture was allowed to react at an internal pressure of 100 mmHg for 30 minutes, and phenol generated was distilled off. Next, the pressure was gradually reduced while the internal temperature was increased to 200° C., and the mixture was allowed to react while phenol was distilled off at 50 mmHg for 30 minutes. Further, the temperature was gradually increased to 220° C. and the pressure was gradually reduced to 1 mmHg, and the mixture was allowed to react under conditions of the same temperature and the same pressure as described above for 30 minutes. The obtained solid content was washed with methanol and dried under reduced pressure, thereby obtaining an intermediate compound.

20 g of toluene and 22 g of the intermediate compound were mixed in a 200 mL flask equipped with a thermometer, a cooling pipe, and a stirrer and heated at about 85° C. 0.19 g of dimethylaminopyridine was added thereto. 30.6 g of methacrylic anhydride was gradually added thereto when the entire solid was expected to be dissolved. The obtained solution was continuously mixed, and the same state was maintained at 85° C. for 3 hours. Next, the solution was cooled to room temperature and added dropwise to methanol vigorously stirred with a magnetic stirrer in a 1 L beaker. The precipitate was washed with a mixed solution of 1 L of methanol and 200 ml of tetrahydrofuran twice, washed with 1 L of hot water twice, and dried at 80° C. under reduced pressure, thereby obtaining a curable resin (A8) having the following repeating unit, containing a methacryloyloxy group with a weight-average molecular weight of 2700 at the terminal, and containing 0% by area of 2,2-bis(4-hydroxy-3,5-dimethylphenyl)propane dimethacrylate.

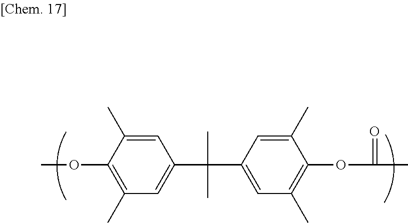

### Synthesis Example 9

113.8 parts by mass of 2,2-(bis(4-hydroxy-3,5-dimethylphenyl)propane, 66.7 parts by mass of 48% sodium hydroxide, and 200 parts by mass of xylene were added to a reaction container equipped with a Dean Stark Trap, a condenser, a nitrogen inlet, a stirrer, and a thermometer, and heated to 140° C. to collect an azeotropic mixture of water and xylene. After complete dehydration for 4 hours, the temperature of the reaction mixture was increased to 200° C. to remove xylene by distillation. Next, 200 parts by mass of N-methyl-2-pyrrolidone, 70.8 parts by mass of 1,4-dibromobenzene, and 0.396 parts by mass of copper(I) chloride were added thereto, and the mixture was stirred at 200° C. for 20 hours. The reaction mixture was cooled to 60° C., 100 parts by mass of N-methyl-2-pyrrolidone, 20.2 parts by mass of triethylamine, and 20.9 parts by mass of methacrylic acid chloride were added thereto, and the mixture was stirred at 60° C. for 10 hours. Next, the reaction mixture was poured little by little into a mixed solution of 2 L of methanol and 100 ml of acetic acid which had been stirred at a high speed, to obtain a precipitate. The precipitate was washed with a mixed solution of 1 L of methanol and 200 ml of tetrahydrofuran twice, washed with 1 L of hot water twice, and dried at 80° C. under reduced pressure, thereby obtaining a curable resin (A9) having the following repeating unit, containing a methacryloyloxy group with a weight-average molecular weight of 2700 at the terminal, and containing 0% by area of 2,2-bis(4-hydroxy-3,5-dimethylphenyl)propane dimethacrylate.

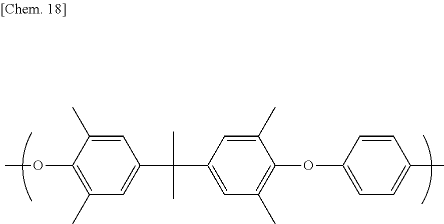

### Synthesis Example 10

A reaction container provided with a stirring device was charged with 113.8 parts by mass of 2,2-bis(4-hydroxy-3,5-dimethylphenyl)propane, 64.0 parts by mass of sodium hydroxide, 0.25 parts by mass of tri-n-butylbenzylammonium chloride, and 2000 parts by mass of pure water, and the mixture was dissolved to prepare an aqueous phase. 125.6 parts by mass of methacrylic acid chloride was dissolved in 1500 parts by mass of methylene chloride to prepare an organic phase.

The aqueous phase was stirred in advance, the organic phase was added to the aqueous phase while the mixture was strongly stirred, and the mixture was allowed to react at 20° C. for 5 hours. Thereafter, the stirring was stopped, the aqueous phase and the organic phase were separated from each other, and the organic phase was washed with pure water 10 times. Next, the methylene chloride was distilled from the organic phase using an evaporator under reduced pressure, and a compound obtained by the reaction was dried and solidified. The obtained compound was dried under reduced pressure, thereby obtaining a curable compound (B1) having the following structure.

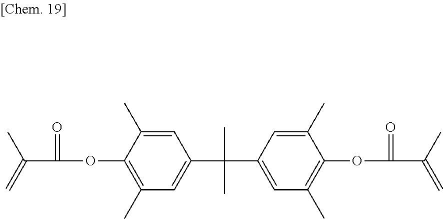 [SMILES: C=C(C)C(=O)Oc1c(C)cc(C(C)(C)c2cc(C)c(OC(=O)C(=C)C)c(C)c2)cc1C]

### <Preparation of Curable Resin Composition>

Samples for evaluation (resin films (cured articles) were prepared by using the curable resins or the curable compounds obtained in the synthesis examples described above based on the curable resin composition blended as listed in Tables 1 and 2 (raw materials and blending amounts) and the conditions (temperatures, times, and the like) described below, and evaluated as examples and comparative examples.

### <Preparation of Resin Film (Cured Article)>

The curable resin composition was placed in a square mold with a size of 5 cm square, sandwiched between stainless steel plates, and set in a vacuum press. The pressure was increased to 1.5 MPa at room temperature and a normal pressure. Next, the pressure was reduced to 10 torr, the temperature was increased to a temperature higher than the heat curing temperature by 50° C. over 30 minutes. Further, the composition was allowed to stand for 2 hours and slowly cooled to room temperature, thereby obtaining a uniform resin film (cured article) with an average film thickness of 100 μm.

### <Evaluation of Dielectric Properties>

In regard to the dielectric properties of the obtained resin film (cured article) in the in-plane direction, the dielectric constant and the dielectric loss tangent at a frequency of 10 GHz were measured by a slit post dielectric resonator method using a network analyzer N5247A (manufactured by Keysight Technologies).

When the dielectric loss tangent is 10.0×1⁻³ or less, there is no problem in practical use, and the dielectric loss tangent is preferably 3.0×1⁻³ or less and more preferably 2.5×1⁻³ or less.

Further, when the dielectric constant is 3 or less, there is no problem in practical use, and the dielectric constant is preferably 2.7 or less and more preferably 2.5 or less.

### <Evaluation of Heat Resistance (Glass Transition Temperature)>

The exothermic peak temperature (heat curing temperature) of the obtained resin film (cured article) was observed by performing measurement under a temperature increase condition of 20° C./min from 30° C. using a DSC device (Pyris Diamond, manufactured by PerkinElmer, Inc.), and the state was maintained at a temperature higher than the measurement temperature by 50° C. for 30 minutes. Next, the glass transition temperature (Tg) (° C.) of the resin film (cured article) was measured by cooling the sample under a temperature decrease condition of 20° C./min to 30° C. and increasing the temperature again under a temperature increase condition of 20° C./min.

When the glass transition temperature (Tg) is 100° C. or higher, there is no problem in practical use, and the glass transition temperature is preferably 150° C. or higher and more preferably 190° C. or higher.

### <Evaluation of Heat Resistance>

The 5% weight loss temperature (Td5) of the obtained resin film (cured article) was measured by performing measurement at a temperature increase rate of 20° C./min in a nitrogen flow of 20 mL/min using s TG-DTA device (TG-8120, manufactured by Rigaku Corporation).

### <Evaluation of Solvent Solubility>

The obtained curable resin composition was dissolved in toluene at a proportion set such that the non-volatile content (mass ratio) reached 50%, the solution was allowed to stand for one week, and the solvent solubility was evaluated based on the appearance of the solution. The evaluation criteria are as follows. Further, when the evaluation result is “◯” or “⊚”, there is no problem in practical use, and “⊚” is preferable as the evaluation result.
⊚: The curable resin composition was completely dissolved.
◯: The curable resin composition was dissolved, but was slightly cloudy.
Δ: A small amount of the curable resin composition remained undissolved.
X: The curable resin composition was mostly undissolved, or the most part thereof remained undissolved.

TABLE 1

| | | Example | Example | Example | Example | Example | Example | Example | Example | Example | Example |
|---|---|---|---|---|---|---|---|---|---|---|---|
| | | 1 | 2 | 3 | 4 | 5 | 6 | 7 | 8 | 9 | 10 |
| Composition | Curable resin (A1) | 99.96 | 99.6 | 99.2 | 98.7 | 96 | 87 | 82 | 72 | 62 | |
| (parts by | Curable resin (A2) | | | | | | | | | | 100 |
| mass) | Curable resin (A3) | | | | | | | | | | |
| | Curable resin (A4) | | | | | | | | | | |
| | Curable resin (A5) | | | | | | | | | | |
| | Curable resin (A6) | | | | | | | | | | |
| | Curable resin (A7) | | | | | | | | | | |
| | Curable resin (A8) | | | | | | | | | | |
| | Curable resin (A9) | | | | | | | | | | |
| | Curable compound | 0.04 | 0.4 | 0.8 | 1.3 | 4 | 13 | 18 | 28 | 38 | |
| | (B1) | | | | | | | | | | |

| | | | | | | | | | | |
|---|---|---|---|---|---|---|---|---|---|---|
| Area % of curable compound | 0.05 | 0.5 | 1.0 | 1.5 | 5.0 | 15 | 20 | 30 | 40 | 7.0 |
| (B) measured by GPC | | | | | | | | | | |
| Dielectric loss tangent (×10⁻³) | 2.0 | 2.0 | 2.0 | 2.0 | 2.0 | 2.0 | 2.0 | 2.0 | 2.0 | 2.0 |
| Dielectric constant | 2.4 | 2.4 | 2.4 | 2.4 | 2.4 | 2.4 | 2.4 | 2.4 | 2.4 | 2.4 |
| Glass transition temperature | 200 | 200 | 200 | 200 | 200 | 200 | 200 | 170 | 165 | 190 |
| Solvent solubility | Δ | ◯ | ⊚ | ⊚ | ⊚ | ⊚ | ⊚ | ⊚ | ⊚ | ⊚ |

TABLE 2

| | | Exam- | Exam- | Exam- | Exam- | Exam | Com- | Com- | Com- | Com- | Com- |
|---|---|---|---|---|---|---|---|---|---|---|---|
| | | ple | ple | ple | ple | ple | parative | parative | parative | parative | parative |
| | | 11 | 12 | 13 | 14 | 15 | Example 1 | Example 2 | Example 3 | Example 4 | Example 5 |
| Composition | Curable resin (A1) | | | | | | 100 | | | | |
| (parts by | Curable resin (A2) | | | | | | | | | | |
| mass) | Curable resin (A3) | 100 | | | | | | | | | |
| | Curable resin (A4) | | 100 | | | | | | | | |
| | Curable resin (A5) | | | | | | | | | 100 | |
| | Curable resin (A6) | | | 100 | | | | | | | |
| | Curable resin (A7) | | | | | | | | | | |
| | Curable resin (A8) | | | | 91 | | | 100 | | | |
| | Curable resin (A9) | | | | | 91 | | | 100 | | |
| | Curable compound | | | | 9 | 9 | | | | | 100 |
| | (B1) | | | | | | | | | | |

| | | | | | | | | | | |
|---|---|---|---|---|---|---|---|---|---|---|
| Area % of curable compound | 7.0 | 8.0 | 8.0 | 10 | 10 | 0 | 0 | 0 | 9.0 | 100 |
| (B) measured by GPC | | | | | | | | | | |
| Dielectric loss tangent (×10⁻³) | 2.3 | 2.1 | 3.0 | 2.2 | 2.0 | 2.0 | 2.2 | 2.0 | 12 | 3.2 |
| Dielectric constant | 2.4 | 2.2 | 2.5 | 2.4 | 2.4 | 2.4 | 2.4 | 2.4 | 3.0 | 2.8 |
| Glass transition temperature | 185 | 135 | 185 | 130 | 190 | 200 | 130 | 190 | 130 | 90 |
| Solvent solubility | ⊚ | ⊚ | ⊚ | ⊚ | ⊚ | X | X | X | ⊚ | ⊚ |

1. A curable resin composition comprising:
a curable resin (A) that has a repeating unit represented by General Formula (1) and contains one or more reactive groups selected from the group consisting of a (meth)acryloyloxy group, a vinylbenzyl ether group, and an allyl ether group as a terminal structure; and
a curable compound (B) represented by General Formula (2), 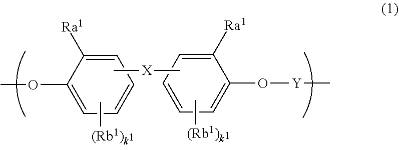
in the formula, Ra¹ and Rb¹ each independently represent an alkyl group having 1 to 12 carbon atoms, an aryl group, an aralkyl group, or a cycloalkyl group, k¹ represents an integer of 0 to 3, X represents a single bond or a hydrocarbon group, and Y is represented by any of General Formulae (3) to (5), 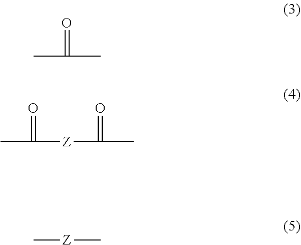
in the formulae, Z represents a hydrocarbon group, 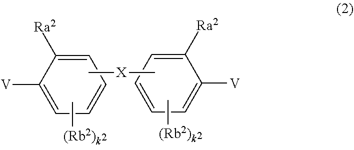
in the formula, Ra² and Rb² each independently represent an alkyl group having 1 to 12 carbon atoms, an aryl group, an aralkyl group, or a cycloalkyl group, k² represents an integer of 0 to 3, X represents a single bond or a hydrocarbon group, and V represents a (meth)acryloyloxy group, a vinylbenzyl ether group, or an allyl ether group,
wherein when a total area % of the curable resin (A) and the curable compound (B) as measured by gel permeation chromatography (GPC) is set to 100, an area % of the curable compound (B) is in a range of 0.5% by area to 30.0% by area.

2. (canceled)

3. The curable resin composition according to claim 1,
wherein General Formula (1) is represented by General Formula (1A), 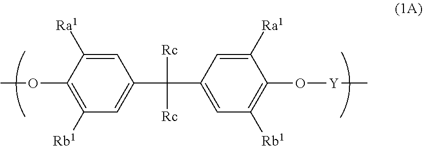
in the formula, Rc represents an alkyl group, an aryl group, an aralkyl group, or a cycloalkyl group, and Ra¹, Rb¹, and Y each have the same definition as described above.

4. The curable resin composition according to claim 1,
wherein Z represents any one of an alicyclic group, an aromatic group, or a heterocyclic group.

5. The curable resin composition according to claim 1,
wherein the terminal structure is a methacryloyloxy group.

6. The curable resin composition according to claim 1,
wherein the curable resin (A) has a weight-average molecular weight of 500 to 5000.

7. A cured article which is obtained by performing a curing reaction on the curable resin composition according to claim 1.

8. A varnish which is obtained by diluting the curable resin composition according to claim 1 with an organic solvent.

9. A prepreg comprising:
a reinforcing base material; and
a semi-cured article of the varnish according to claim 8 which is impregnated into the reinforcing base material.

10. A circuit board which is obtained by laminating the prepreg according to claim 9 and copper foil and performing thermocompression bonding and molding.

11. The curable resin composition according to claim 2,
wherein General Formula (1) is represented by General Formula (1A), 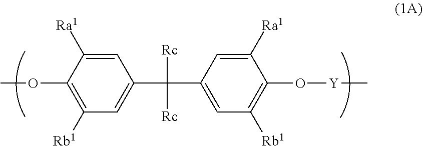
in the formula, Rc represents an alkyl group, an aryl group, an aralkyl group, or a cycloalkyl group, and Ra¹, Rb¹, and Y each have the same definition as described above.

12. The curable resin composition according to claim 2,
wherein Z represents any one of an alicyclic group, an aromatic group, or a heterocyclic group.

13. The curable resin composition according to claim 3,
wherein Z represents any one of an alicyclic group, an aromatic group, or a heterocyclic group.

14. The curable resin composition according to claim 2,
wherein the terminal structure is a methacryloyloxy group.

15. The curable resin composition according to claim 3,
wherein the terminal structure is a methacryloyloxy group.

16. The curable resin composition according to claim 2,
wherein the curable resin (A) has a weight-average molecular weight of 500 to 5000.

17. The curable resin composition according to claim 3,
wherein the curable resin (A) has a weight-average molecular weight of 500 to 5000.

18. A cured article which is obtained by performing a curing reaction on the curable resin composition according to claim 2.

19. A cured article which is obtained by performing a curing reaction on the curable resin composition according to claim 3.

20. A varnish which is obtained by diluting the curable resin composition according to claim 2 with an organic solvent.

21. A varnish which is obtained by diluting the curable resin composition according to claim 3 with an organic solvent.
